(19) United States
(12) Patent Application Publication
(10) Pub. No.: US 2008/0001264 A1
(43) Pub. Date: Jan. 3, 2008

(54) Exposed top side copper leadframe manufacturing

(75) Inventor: Bernhard P. Lange, Freising (DE)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/480,801

(22) Filed: Jul. 3, 2006

(51) Int. Cl. H01L 23/495

(52) U.S. Cl. 257/666

(57) ABSTRACT

In a method and system for fabricating a leadframe (100), a thickness of bondable areas (150, 152 and 154) of the leadframe (100) is reduced. A plating finish (160) is applied to a surface of the leadframe (100), including the surface of the bondable areas (150, 152 and 154) to provide a smooth texture. A selective portion (102) of the surface is removed by grinding off the plating finish (160) on the selective portion (102) to provide a rough texture while substantially preserving the smooth texture on the bondable areas (150, 152 and 154). Removal of the plating finish (160) on the selective portion (102) causes the selective portion (102) to form the rough texture, compared to the smooth texture of the plating finish (160). The rough texture provides increased adhesion to a polymeric compound compared to an adhesion provided by the smooth texture. Bondability of the bondable areas (150, 152 and 154) is maintained by preserving the smooth texture of the plating finish (160).

### BACKGROUND

The present invention is related in general to the field of semiconductor device packaging and more specifically to fabrication of leadframes for integrated circuit devices.

It is well known that a leadframe of a semiconductor device provides a stable support base for securely positioning a semiconductor chip or die, usually an integrated circuit (IC) chip. The leadframe also offers a plurality of conductive segments to bring various electrical conductors into close proximity of the chip. A gap between the (“inner”) end of the conductive segments and the conductor pads on the IC surface is typically bridged by thin metallic wires (also referred to as bond wires that are typically made of gold), which are individually bonded to the IC contact pads and the leadframe segments. The ends of the conductive segment remote from the IC chip (referred to as the “outer” end or the “lead”) are electrically and mechanically connected to external circuitry.

It has been a common practice to manufacture single piece leadframes from thin sheets of metal. Commonly used metals may include copper, copper alloys, iron-nickel alloys such as “Alloy 42”, and invar. A desired shape of the leadframe may be etched or stamped from an original sheet. An individual segment of the leadframe typically takes the form of a thin metallic strip with its particular geometric shape determined by each application.

After assembly on the leadframe, most ICs are encapsulated, commonly by plastic material in a molding process. A conventional method for providing suitable bondability (or ability to bond) for the interconnection between the bond wires and leads of a leadframe is to pre-plate or coat the bonding area of the leadframe prior to the encapsulation. One related example of a pre-plating process is described in U.S. Pat. No. 6,545,342 entitled “Pre-finished leadframe for semiconductor devices and method of fabrication”, which is incorporated herein by reference.

However, traditional tools and methods for fabricating a leadframe may be inadequate to ensure that the molding compound (usually, but not limited to, an epoxy-based thermoset compound that is typically designed for copper surfaces), and the die attach compound provide sufficient adhesion to the pre-plated finish of the leadframe.

### SUMMARY

Applicants recognize an existing need for an improved method and system for fabricating a pre-plated leadframe of semiconductor device; and the need for an improved technique to provide sufficient adhesive bonding between the molding compound, and the die attach compound with the leadframe, absent the disadvantages found in the prior techniques discussed above.

The foregoing need is addressed by the teachings of the present disclosure, which relates to a system and method for fabricating pre-plated leadframes. According to one embodiment, in a method and system for fabricating a leadframe, a thickness of bondable areas of the leadframe is reduced. A plating finish is applied to a surface of the leadframe, including the surface of the bondable areas to provide a smooth texture. A selective portion of the surface is removed by grinding off the plating finish on the selective portion to provide a rough texture while substantially preserving the smooth texture on the bondable areas. Removal of the plating finish on the selective portion causes the selective portion to form the rough texture, compared to the smooth texture of the plating finish. The rough texture provides increased adhesion to a polymeric compound compared to an adhesion provided by the smooth texture. Bondability of the bondable areas is maintained by preserving the smooth texture of the plating finish.

In one aspect of the disclosure, a semiconductor device includes a leadframe stamped from a metal sheet. The leadframe includes bondable areas that are downset relative to a top surface of the leadframe. A plating finish covers the entire surface of the leadframe including the bondable areas. The plating finish is selectively removed from the top surface to expose the metal sheet while substantially preserving the plating finish on the bondable areas. An integrated circuit (IC) chip or die is attached to the exposed metal sheet by a chip attach compound. A plurality of bond wires electrically couple the IC chip to the bondable areas. A molding compound encapsulates the IC chip, the bondable areas, the plurality of bond wires, and at least a portion of the leadframe depending on whether the leadframe is leadless or with leads.

Several advantages are achieved by the method and system according to the illustrative embodiments presented herein. The embodiments advantageously provide for improved adhesion between polymeric compounds and a surface of the leadframe. A grinding treatment of the top surface of the leadframe advantageously removes the plating finish and roughens the top surface, thereby improving the adhesion. The grinding treatment advantageously preserves the plating finish in the bondable and other selected areas that are downset relative to the top surface. In addition, by retaining the plating finish in the bondable areas, the bondability of the leadframe is advantageously retained.

### BRIEF DESCRIPTION OF THE DRAWINGS

FIG. 1A illustrates a simplified and schematic cross section of a leadframe, according to an embodiment;

FIGS. 1B and 1C illustrate a simplified and schematic cross section of the leadframe described with reference to FIG. 1A having recessed bondable areas, according to an embodiment;

FIG. 1D illustrates a simplified and schematic cross section of the leadframe described with reference to FIGS. 1A, 1B and 1C having a plating finish, according to an embodiment;

FIG. 1E illustrates a simplified and schematic cross section of the leadframe described with reference to FIGS. 1A, 1B, 1C and 1D having a roughened top surface and plated recessed bondable areas, according to an embodiment;

FIG. 1F illustrates a simplified and schematic cross section of a partially assembled semiconductor device including the leadframe described with reference to FIGS. 1A, 1B, 1C, 1D and 1E, an integrated circuit chip and bond wires, according to an embodiment;

FIG. 1G illustrates a simplified and schematic cross section of a semiconductor device assembled as a leadless package, according to an embodiment;

FIG. 1H illustrates a simplified and schematic cross section of a semiconductor device assembled as a package with leads, according to an embodiment;

FIG. 2A is a flow chart illustrating a method for fabricating a semiconductor device, according to an embodiment;

FIG. 2B is a flow chart illustrating additional details of a method for providing a leadframe described with reference to FIG. 2A, according to an embodiment; and

FIG. 2C is a flow chart illustrating additional details of a method for attaching an IC chip described with reference to FIG. 2A, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices or components described herein may be implemented as hardware (including discrete components, integrated circuits and systems-on-a-chip ‘SoC’), firmware (including application specific integrated circuits and programmable chips) and/or software or a combination thereof, depending on the application requirements. Similarly, the functionality of various mechanical elements, members, and/or components for forming modules, sub-assemblies and assemblies assembled in accordance with a structure for an apparatus may be implemented using various materials and coupling techniques, depending on the application requirements.

Traditional tools and methods for fabricating a leadframe may be inadequate to ensure that a polymeric compound (usually an epoxy-based thermoset compound that are typically designed for adhesion to copper surfaces), provide sufficient adhesion to the smooth pre-plated finish of the leadframe. As a result, improper adhesion may cause delamination, moisture ingress, and corrosion, which may lead to a failure of the semiconductor device. This problem may be addressed by an improved system and method for fabricating a leadframe. According to an embodiment, in an improved system and method for fabricating a leadframe, a thickness of bondable areas of the leadframe is reduced. A plating finish is applied to a surface of the leadframe, including the surface of the bondable areas to provide a smooth texture. A selective portion of the surface is removed by grinding off the plating finish on the selective portion to provide a rough texture while substantially preserving the smooth texture on the bondable areas. Removal of the plating finish on the selective portion causes the selective portion to form the rough texture, compared to the smooth texture of the plating finish. The rough texture provides increased adhesion to a polymeric compound compared to an adhesion provided by the smooth texture. Bondability of the bondable areas is maintained by preserving the smooth texture of the plating finish.

The following terminology may be useful in understanding the present disclosure. It is to be understood that the terminology described herein is for the purpose of description and should not be regarded as limiting.

Leadframe—A leadframe is a conductive support or frame structure for securely attaching an integrated circuit (IC) chip or die during packaging and assembly of a semiconductor device. The leadframe typically includes a chip mount pad (also referred to as a die paddle) for attaching the IC chip, and a plurality of conductive or lead segments to connect to external circuits. A gap between the (“inner”) end of the conductive segments and the conductor pads on the IC surface are typically bridged by thin metallic bond wires (typically made from gold), which are individually bonded to the IC contact pads and the leadframe segments. The ends of the conductive segment remote from the IC chip (referred to as “outer” ends) are electrically and mechanically connected to external circuitry. The packaging and assembly also includes encapsulating the IC chip, the bond wires, and at least a portion of the conductive segments by a polymeric compound.

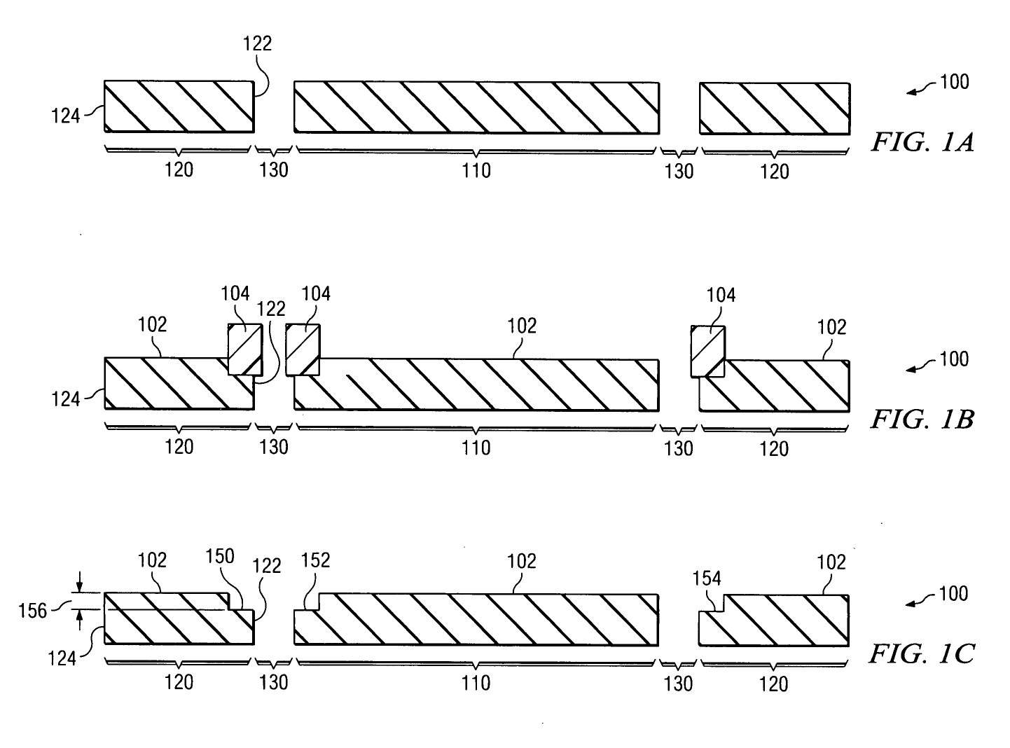

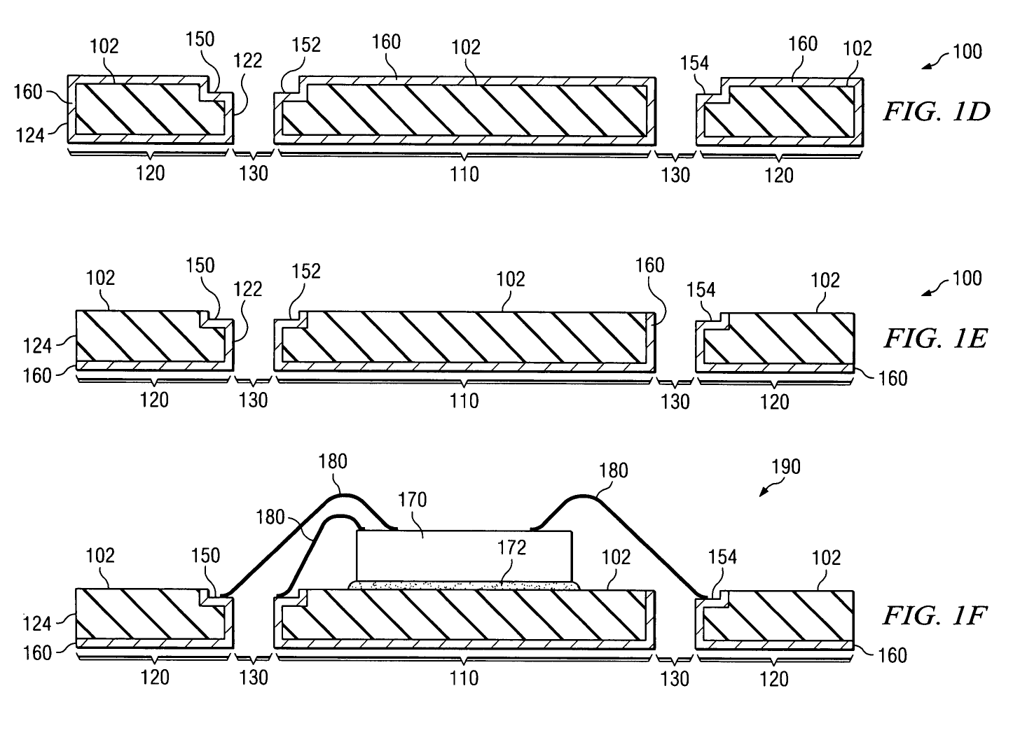

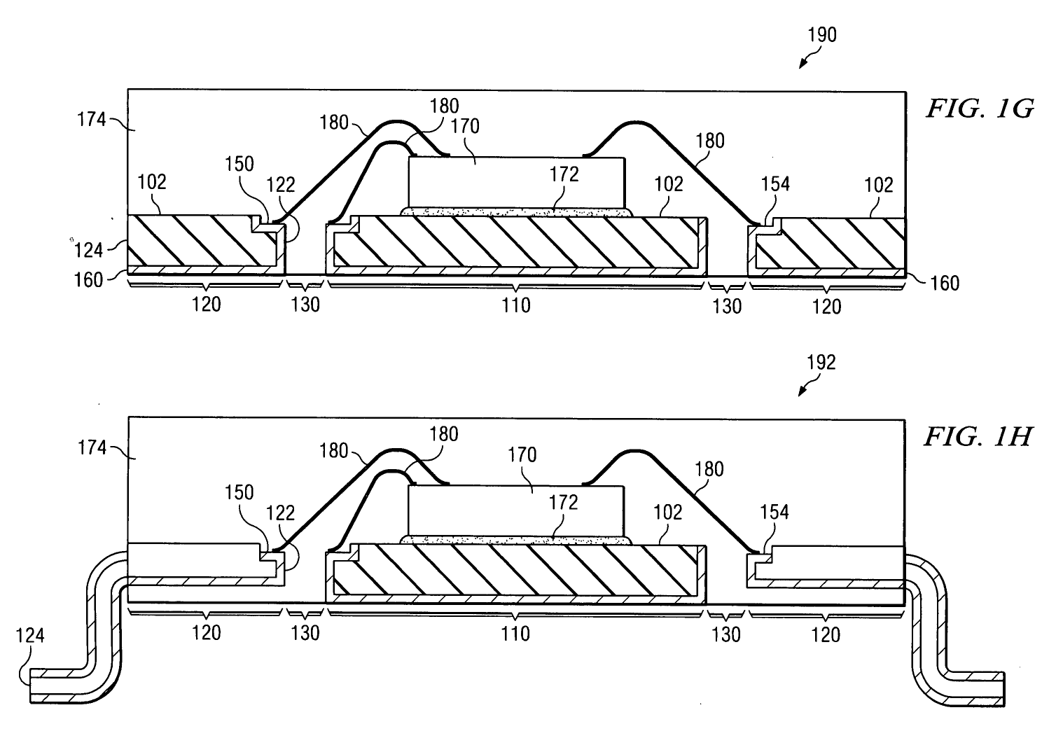

The fabrication of a semiconductor device having a pre-plated leadframe that provides improved adhesion to polymeric compounds is described with reference to FIGS. 1A, 1B, 1C, 1D, 1E, 1F, and 1G.

FIG. 1A illustrates a simplified and schematic cross section of a leadframe 100 stamped (or etched) from a conductive material such as a metal sheet, according to an embodiment. In the depicted embodiment, the leadframe 100 includes a base structure having a chip mount pad 110 and a plurality of conductive or lead segments 120, with each one of the plurality of conductive segments having an inner end 122 and an outer end 124. A gap 130 separates the inner end 122 from the chip mount pad 110. The metal sheet is preferably made of copper or copper alloy. Other choices for the metal sheet may include brass, aluminum, an iron nickel alloy such as “Alloy 42”, and invar. The thickness of the metal sheet may be in the range from about 100 to 400 micro meters, although thinner or thicker sheets may be possible.

FIGS. 1B and 1C illustrate a simplified and schematic cross section of the leadframe 100 described with reference to FIG. 1A having recessed bondable areas, according to an embodiment. Before the plating process, intended wire bond areas 150, 152, and 154 (also referred to as bondable areas) of the leadframe 100 are identified on a selective surface 102, e.g., the top surface, the bottom surface, or any other selective portion of the entire surface. Although three bondable areas 150, 152, and 154 are shown, the number of bondable areas may vary for each application. The identified bondable areas 150, 152, and 154 are recessed or downset 156 relative to the selective surface 102 by using stamp patterns or etch masks 104 in a stamping or an etching process. In an exemplary, non-depicted embodiment, if an external lead package option is selected for the leadframe 100, the external leads may also be recessed relative to the top surface, similar to the bondable areas. Additional detail of the recessed external leads are described with reference to FIG. 1H. The size and shape of each one of the stamp patterns or etch masks may vary by application. In an embodiment, the downset 156 or a thickness of the bondable areas 150, 152, and 154 may be reduced by approximately 10 percent to 50 percent compared to an initial thickness of the leadframe 100.

FIG. 1D illustrates a simplified and schematic cross section of the leadframe 100 described with reference to FIGS. 1A, 1B and 1C having recessed bondable areas and a plating finish, according to an embodiment. The entire surface of the leadframe 100 including the selective surface 102 and the bondable areas 150, 152, and 154 that are recessed are covered by a plating finish 160 layer using a plating process. Covering the surface with the plating finish 160 provides a smooth texture compared to the texture of the original surface before the plating process. In a particular embodiment, the plating finish 160 is fabricated from nickel, silver, palladium, and gold or a combination thereof. A thickness of the plating finish 160 may be about 100 nanometers to about 1000 nanometers, and a surface of the plating finish 160 is substantially smoother compared to the selective surface 102 prior to the plating.

FIG. 1E illustrates a simplified and schematic cross section of the leadframe 100 described with reference to FIGS. 1A, 1B, 1C and 1D having a roughened top surface and plated recessed bondable areas, according to an embodiment. The plating finish 160 layered on the selective surface 102 of the leadframe 100 is removed by a grinding process to provide the rough texture. Removal of the plating finish 160 due to the grinding process thus causes the metal sheet such as copper to be exposed, thereby creating the rough texture of the selective surface 102. In an embodiment, the grinding process may include wet or dry grinding, and may use a grinder with grinding tools such as a wheel, pad, belt, and band sanders. The grinding process may be advantageously performed in-line directly after the plating process on a reel-to-reel leadframe or on singulated leadframe strips. Other processes for the removal of the plating finish 160 layered on the selective surface 102 area may also be deployed. The in-line grinding process is advantageously accomplished by deploying existing or installed fabrication equipment, thereby minimizing investment in acquiring new manufacturing machines. The grinding process (or any other similar process) for the removal of the plating finish 160 from the selective surface 102 advantageously results in an exposure of the metal sheet and roughening of the selective surface 102, thereby providing improved adhesion to polymeric compounds.

FIG. 1F illustrates a simplified and schematic cross section of a partially assembled semiconductor device 190 including the leadframe described with reference to FIGS. 1A, 1B, 1C, 1D and 1E, an integrated circuit chip and bond wires, according to an embodiment. An integrated circuit (IC) chip 170 is securely attached to the chip mount pad 110 having the rough texture, e.g., the selective surface 102, by a layer of a polymeric compound such as a chip attach compound 172. The modified surface of the leadframe 100 having the rough texture is better suited for adhesion to polymer (or polymeric) compounds used for chip attachment and device encapsulation compared to the adhesion to the smooth texture provided by the plated finish 160. For chip attachment, epoxy or polyimide based materials may be used, preferably polymerized at relatively low temperatures (e.g., between 150 and 200 degrees Centigrade). For device encapsulation, epoxy based molding compounds such as a molding compound 174, having polymerization temperatures between about 150 to 180 degrees Centigrade may be used. The improved adhesion between the roughened surface and the chip attach compound 172 and the molding compound 174 provides improved protection against delamination, moisture ingress, and corrosion.

A plurality of bond wires 180 are provided across the gap 130 to electrically couple contact pads of the IC chip 170 to a corresponding one of the bondable areas 150, 152, and 154 that are recessed and covered by the plating finish 160. The bond wires are generally fabricated from gold, but may also be fabricated from copper, aluminum, and alloys thereof. As described earlier, the smooth texture of the plating finish 160 preserves the bondability of each one of the plurality of bond wires 180. The outer end 124 may not have the plating finish 160 on the side of the package, since the plating finish 160 portion of the outer end 124 may be cut during package separation.

In an embodiment, the IC chip 170 is one of one of a microprocessor, a digital signal processor, a radio frequency chip, a memory, a microcontroller and a system-on-a-chip or a combination thereof.

FIG. 1G illustrates a simplified and schematic cross section of the semiconductor device 190 described with reference to FIG. 1F and assembled as a leadless package, according to an embodiment. In the depicted embodiment, the polymeric compound which may be the epoxy based molding compound 174 is used to encapsulate the semiconductor device 190, which includes the leadframe 100, the IC chip 170, the bondable areas 150, 152, and 154, and the plurality of bond wires 180. In the depicted embodiment, for a leadless package the inner end 122 of each one of the plurality of conductive segments 120 is encapsulated and the outer end 124 of each one of the plurality of conductive segments 120 is cut.

FIG. 1H illustrates a simplified and schematic cross section of a semiconductor device 192 assembled as a package with leads, according to an embodiment. The semiconductor device 192 is substantially the same as the semiconductor device 190 described with reference to FIG. 1H except for the packaging, e.g., with leads or leadless. In the depicted embodiment, the polymeric compound which may be the epoxy based molding compound 174 is used to encapsulate the semiconductor device 190, which includes the leadframe 100, the IC chip 170, the bondable areas 150, 152, and 154, and the plurality of bond wires 180. In the depicted embodiment, the semiconductor device 192 assembled as a package with leads the inner end 122 of the plurality of conductive segments 120 is encapsulated, whereas the outer end 124 is exposed for external connections. Portion of the plurality of conductive segments 120 that are external to encapsulated chip, e.g., the outer end 124, is recessed, similar to the bondable areas 150, 152, and 154, to advantageously preserve the smooth texture of the plating finish 160 on the selective surface 102 that is external to the polymeric compound such as the molding compound 174. In the depicted embodiment, the IC chip 170 attached to the chip mount pad 110 is downset relative to the inner end 122. In this embodiment, the downset process is performed after performing the grinding process described with reference to FIG. 1E.

In an embodiment, the semiconductor devices 190 and 192 having the IC chip 170 is one of one of a microprocessor, a digital signal processor, a radio frequency chip, a memory, a microcontroller and a system-on-a-chip or a combination thereof.

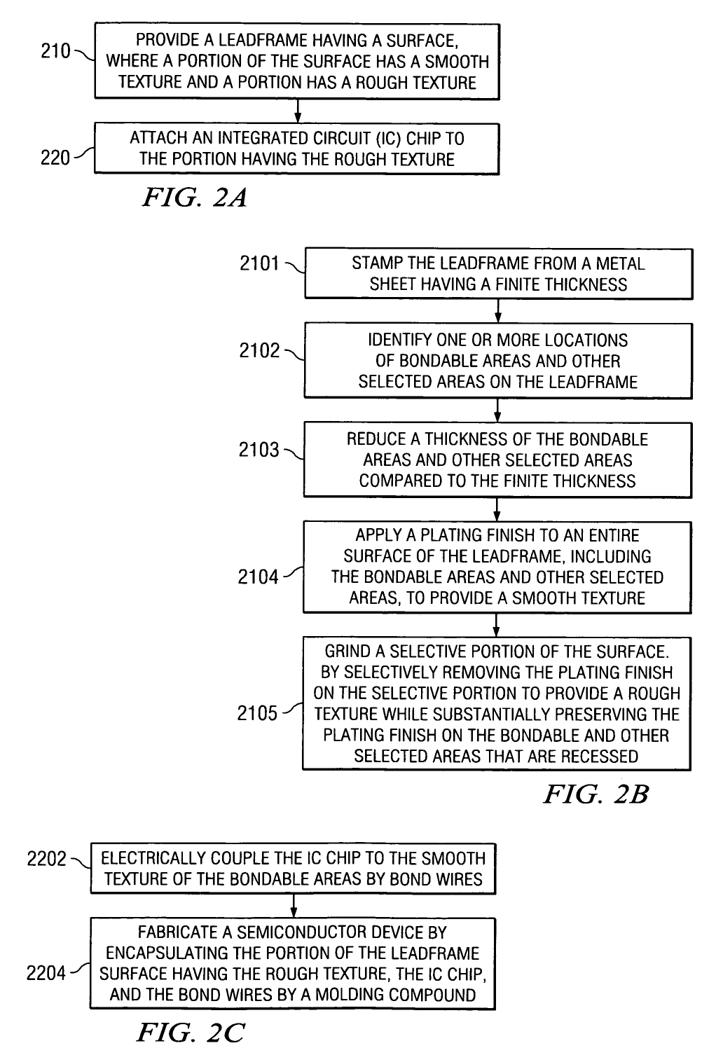

FIG. 2A is a flow chart illustrating a method for fabricating a semiconductor device, according to an embodiment. In a particular embodiment, the semiconductor device is substantially the same as the semiconductor device 190 and 192 described with reference to FIGS. 1A, 1B, 1C, 1D, 1E, 1F, 1G and 1H. At step 210, a leadframe, e.g., the leadframe 100, having a surface that has a smooth texture portion and a rough texture portion is provided. At step 220, an integrated circuit (IC) chip is attached to the portion having the rough texture.

FIG. 2B is a flow chart illustrating additional details of a method for providing a leadframe described with reference to FIG. 2A, according to an embodiment. At step 2101, the leadframe is stamped from a metal sheet having a finite thickness. The leadframe provides a chip mount pad to attach the integrated circuit (IC) chip, and a plurality of conductive or lead segments for electrical coupling with external circuits. At step 2102, one or more locations of bondable areas on the leadframe are identified. If a packaging option for the leadframe uses outside leads for electrical connections, the external lead surfaces (external to the molding compound) may also be selected as one of the bondable areas. At step 2103, a thickness of the bondable or other selected areas is reduced compared to the finite thickness. At step 2104, a plating finish is applied to an entire surface of the leadframe, including the bondable areas and other selected areas, to provide a smooth texture. At step 2105, a selective portion of the surface is subjected to a grinding operation to provide a rough texture from an initial smooth texture. The grinding selectively removes the plating finish on the selective portion to from the rough texture while substantially preserving the smooth texture on the bondable areas that are recessed.

FIG. 2C is a flow chart illustrating additional details of a method for attaching an IC chip described with reference to FIG. 2A, according to an embodiment. At step 2202, the IC chip is electrically coupled to the smooth texture of the bondable areas by bond wires. At step 2204, a semiconductor device is fabricated by encapsulating the portion of the leadframe surface having the rough texture, the IC chip, and the bond wires by a molding compound.

Various steps described above with reference to FIGS. 2A, 2B and 2C may be added, omitted, combined, altered, or performed in different orders. For example, the step 2105 may be followed by a step to downset the chip mount pad for fabricating a semiconductor device packaged with leads.

Several advantages are achieved by the method and system according to the illustrative embodiments presented herein. The embodiments advantageously provide for improved adhesion between polymeric compounds and a surface of the leadframe. A grinding treatment of the top surface of the leadframe advantageously removes the plating finish and roughens the top surface, thereby improving the adhesion. The grinding treatment is applied to advantageously preserve the plating finish in the bondable and other selected areas that are downset relative to the top surface. In addition, by retaining the plating finish in the bondable areas, the bondability of the leadframe is advantageously retained.

Although illustrative embodiments have been shown and described, a wide range of modification, change and substitution is contemplated in the foregoing disclosure and in some instances, some features of the embodiments may be employed without a corresponding use of other features. Those of ordinary skill in the art will appreciate that the hardware and methods illustrated herein may vary depending on the implementation. For example, while certain aspects of the present disclosure have been described in the context of conventional mounting with wire bonding, those of ordinary skill in the art will appreciate that the processes disclosed are capable of being used for assembly of semiconductor devices using different types of mounting techniques such as flip chip type mount, and/or package types including plastic dual in-line packages (PDIPs), small outline ICs (SOICs), quad flat packs (QFPs), quad flat no-lead (QFN), thin QFPs (TQFPs), SSOPs, TSSOPs, TVSOPs, and similar other leadframe-based packages.

The methods and systems described herein provide for an adaptable implementation. Although certain embodiments have been described using specific examples, it will be apparent to those skilled in the art that the invention is not limited to these few examples. The benefits, advantages, solutions to problems, and any element(s) that may cause any benefit, advantage, or solution to occur or become more pronounced are not to be construed as a critical, required, or an essential feature or element of the present disclosure.

The above disclosed subject matter is to be considered illustrative, and not restrictive, and the appended claims are intended to cover all such modifications, enhancements, and other embodiments, which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A semiconductor device comprising:
a leadframe having a surface, wherein a portion of the surface has a smooth texture and a portion has a rough texture; and
an integrated circuit (IC) chip attached to the portion having the rough texture.

2. The device of claim 1, wherein the leadframe includes a plating finish covering the surface to provide the smooth texture, wherein the portion having the smooth texture includes bondable areas that are downset relative to a selective portion of the surface.

3. The device of claim 2, wherein the selective portion of the surface is a top surface of the leadframe.

4. The device of claim 2, wherein the plating finish includes nickel, silver, palladium, and gold or a combination thereof.

5. The method of claim 2, wherein the downset reduces a thickness of the bondable areas by approximately 10 percent to 50 percent compared to an initial thickness of the leadframe.

6. The device of claim 2, wherein the selective portion of the surface is modified by a grinder to provide the rough texture, wherein the grinder is operable to substantially preserve the smooth texture of the bondable areas.

7. The device of claim 1 further comprising:
a plurality of bond wires to electrically couple the IC chip to the portion having the smooth texture; and
a molding compound to encapsulate the IC chip, the plurality of bond wires, and the portion of the surface having the rough texture.

8. The device of claim 7 further comprising:
a chip mount pad having the portion of the rough texture for attaching the IC chip, and having the portion of the smooth texture to couple the plurality of bond wires; and
a plurality of conductive segments each having a first end near the chip mount pad that has the smooth texture, and a second end remote from the chip mount pad that has the rough texture.

9. The device of claim 1, wherein the IC chip is attached to the portion having the rough texture by a chip attach compound, wherein the rough texture provides improved adhesion to the chip attach compound compared to the adhesion between the chip attach compound and the smooth texture.

10. The device of claim 1, a molding compound encapsulates the IC chip and the portion of the surface having the rough texture, wherein the rough texture provides improved adhesion to the molding compound compared to the adhesion between the molding compound and the smooth texture.

11. The device of claim 8, wherein the second end of the plurality of conductive segments is cut to form a leadless package.

12. The device of claim 8, wherein the second end of the plurality of conductive segments is not encapsulated to form a leaded package.

13. The device of claim 1, wherein the IC chip is one of one of a microprocessor, a digital signal processor, a radio frequency chip, a memory, a microcontroller, and a system-on-a-chip or a combination thereof.

14. A method for fabricating a semiconductor device, the method comprising:
providing a leadframe having a surface, wherein a portion of the surface has a smooth texture and a portion has a rough texture; and
attaching an integrated circuit (IC) chip to the portion having the rough texture.

15. The method of claim 14, wherein the smooth texture and the rough texture of the surface of the leadframe is provided by:
reducing a thickness of bondable areas of the leadframe;
applying a plating finish to the surface of the leadframe, the surface including the bondable areas to provide the smooth texture; and
grinding a selective portion of the surface to selectively remove the plating finish on the selective portion to provide the rough texture, wherein selective removal of the plating finish substantially preserves the plating finish on the bondable areas.

16. The method of claim 15 further comprising:
stamping the leadframe from a metal sheet; and
identifying locations of the bondable areas on the leadframe.

17. The method of claim 15 further comprising:
wirebonding the IC chip to the portion having the smooth texture; and
encapsulating the leadframe and the IC chip by a molding compound.

18. The method of claim 15, wherein the thickness of the bondable areas is reduced by approximately 10 percent to 50 percent compared to an initial thickness of the leadframe.

19. The method of claim 17, wherein the molding compound forms an increased adhesion to the rough texture in response to the grinding compared to the smooth texture before the grinding.

20. The method of claim 14, wherein the IC chip is one of one of a microprocessor, a digital signal processor, a radio frequency chip, a memory, a microcontroller, and a system-on-a-chip or a combination thereof.
